(19) United States
(12) Patent Application Publication
(10) Pub. No.: US 2007/0124635 A1
(43) Pub. Date: May 31, 2007

(54) INTEGRATION CIRCUIT AND TEST METHOD OF THE SAME

(75) Inventor: Toshihiko Yokota, Kyoto-shi (JP)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/555,389

(22) Filed: Nov. 1, 2006

(30) Foreign Application Priority Data
Nov. 7, 2005 (JP) 2005-322494

(51) Int. Cl. G01R 31/28

(52) U.S. Cl. 714/731

(57) ABSTRACT

An object of the present invention is to realize an at-speed test on a latch-to-latch path (a cross domain path) between different clock domains. In order to achieve the object, the present invention provides an integrated circuit which includes: a first flip-flop which is capable of flushing and which operates by using a first clock signal CLK 1; a second flip-flop DFF 2 which operates by using a second clock signal CLK 2, and which is connected to the first flip flop; and a third flip-flop DFF 3 which operates by using the second clock signal CLK 2, and which is connected to the first flip-flop. A test on a path between the first and second flip-flops is carried out in a manner that test data is released and captured on receipt of the clock signal CLK 2 between the second flip-flop DFF 2 and the third flip-flop DFF 3 via the first flip-flop DFF 1, and that the test data is flushed by the first flip-flop DFF 1.

### BACKGROUND OF THE INVENTION

The present invention relates to a test of an integrated circuit such as ASIC, and particularly relates to an integrated circuit for realizing a test on a path between clock domains, and to a test method thereof.

When an application specific integrated circuit (ASIC) designed and manufactured for a particular use is manufactured, an LSSD (Level-Sensitive Scan Design) scan test (hereinafter, referred to as LSSD test) using an LSSD latch is widely carried, as a method of judging whether a chip is conforming or nonconforming.

FIG. 7 is a schematic diagram of a circuit configuration for carrying out the LSSD test.

As shown in FIG. 7, LSSD latches (flip-flops) 200 are provided respectively to the input and output sides of each of combinational circuits (circuits subject to a test) in a chip (an integrated circuit) in order to carry out the LSSD test. Furthermore, all the LSSD latches 200 in the chip are connected via a plurality of scan chains.

The LSSD latch 200 is configured by combining two D latches which are a master latch 201 and a slave latch 202. The master latch 201 includes an input of an A clock, a scan input controlled by using the A clock, an input of a C clock, and a data input controlled by using the C clock. The slave latch 202 is connected to a B clock. When the B clock is at a high level, the data of the master latch 201 is inputted to the slave latch 202.

In a normal operation, the A clock is fixed at a low level, and data is held by using the B and C clocks. On the other hand, when the LSSD test is carried out, the A and B clocks are used for inputting a test pattern (test data) and for outputting a test result.

The sequence of a static LSSD test on the circuit in FIG. 7 is as follows.

Firstly, a test pattern is set in the input side of the LSSD latch 200 via the scan chain by using the A and B clocks (hereinafter, the scan load). After the scan load is finished, the C clock is hit and an output of the combinational circuit is captured in the LSSD latch 200 on the output side. Subsequently, a value captured in the LSSD latch 200 is observed by scan-out (hereinafter, scan unload). It is possible to judge whether logic is correct or incorrect in each combinational circuit by comparing a value obtained by this scan unload with an expected value figured out previously.

Today, it has been progressing not only that an integrated circuit such as ASIC is constructed in a larger scale and with higher density, but also that the integrated circuit operates at higher speed. Especially, the manufacturing process has been becoming more complicated, and the number of steps has been increasing. Therefore, unevenness in semiconductors' speed has been becoming wide. Hence, it is necessary to check not only whether logic is correct or incorrect, but also whether a circuit operates normally at a clock frequency upon operation. Thus, it is important to carry out a test (at-speed test) of a circuit in an operating status (at speed) rather than a static test similar to the above. However, when an operating clock in the LSSD test is provided directly from a large scale integration (LSI) tester, which is an external apparatus, with the configuration shown in FIG. 7, it is difficult to carry out an operating test. This is because an operating clock provided from the LSI tester is slower than an original operating clock (an internal frequency) of an integrated circuit (a chip).

Therefore, in order to carry out the at-speed test, the test needs to be carry out by using the same operating clock as that in the actual operation of the LSI (for example, a clock generated in a PLL circuit in the LSI). However, although an at-speed test has been realized for a latch-to-latch path within a clock domain in the LSI (that is, a part of the circuits operating at the same clock), an at-speed test has not been realized for a latch-to-latch path between different clock domains (hereinafter, a cross domain path). Moreover, from the viewpoint of a data transfer rate between different kinds of interfaces, it is becoming more important nowadays to test a transfer rate between different clock domains.

As a conventional technique to carry out a test on a part of circuits spanning different clock domains, there is a test method called an AC-delay test. This is a method of testing a cross domain path by providing a release clock and a capture clock at approximately 50 MHz from a tester. Furthermore, as another conventional technique, a method and an apparatus have been proposed for carrying out a test by use of a clock for test (hereinafter, the test clock) (for example, refer to Japanese Patent Translation Publication No. 2003-513286). In the conventional technique cited in this document, the test clock is used as the capture clock, while a local clock of each domain (a clock in actual operation generated by the PLL circuit) is used as the release clock. Consequently, it is made possible to carry out the test in a state similar to the actual operation by arranging how quickly the release clock is caused to hit the capture clock.

As described above, not only the static test to check whether the logic is correct or incorrect but also the test to guarantee alternating-current (AC) operation are becoming significantly important for a today's integrated circuit in which its performance has been more improved, and in which its speed has been enhanced. In a test carried out by inputting the operation clock (test clock) from an LSI tester, since the operating clock is slow, the accuracy of the test is not improved, thereby leading to deterioration in fraction defective after shipment. Hence, there is a need to carry out the at-speed test in which a test is carried out by use of the same clock as that in the actual operation of the LSI. However, the at-speed test on the clock domain path has not been realized yet.

In the AC delay test carried out conventionally, the release-capture operation is performed by use of the B and C clocks which are operating clocks in the LSSD test shown in FIG. 7. However, there are problems that timing is not set accurately (so called timing creation), since these clocks are not used in the actual operation, and that there is a large difference in the control over a time when a clock arrives at a latch since the clock is provided from a tester channel.

In the conventional technique cited in Patent Document 1, a complicated test control circuit is provided in the LSI in order to carry out the test. Therefore, although it is possible to carry out the test in a state similar to the at-speed test, there are problems that the circuit scale of the LSI becomes large, and that timing close becomes difficult.

### SUMMARY OF THE INVENTION

The present invention has been made in view of the above technical problems, and an object of the present invention is to realize an at-speed test on a cross domain path.

The present invention to achieve the above object is realized with the following circuit configuration. This integrated circuit includes: a first flip-flop which operates by using a first clock signal and which is able to perform flush operation; a second flip-flop which operates by using a second clock signal, which is connected to a combinational circuit connected to the output of the first flip-flop, and which is able to perform the flush operation; a third flip-flop which operates by using the second clock, and which is connected to the input of the first flip-flop; and a fourth flip-flop which operates by using the first clock signal, and which is connected to the output of the second flip-flop. Then, a test on a path between the first and second flip-flops and clocks related to them is carried out in: a test mode that test data is released by using the second clock signal from the third flip-flop, is flushed by the first flip-flop, and is captured in the second flip-flop; and a test mode that test data is released by using the first clock signal from the first flip-flop, is flushed by the second flip-flop, and is captured in the fourth flip-flop. Here, the path between the first and second flip-flops is a cross domain path.

More particularly, the first and second flip-flops can be configured of MUXSCAN flip-flops or the LSSD latches used for an LSSD scan test. Moreover, the third flip-flop can be a flip-flip used in function, which is allocated in a vicinity of the first flip-flop, and which is included in a domain operating by using the second clock signal. When such a flip-flop does not exist in a system, it is possible to provide, as the third flip-flop, a flip-flop dedicated to release or capture test data. Similarly, the fourth flip-flop can be a flip-flop used in function, which is located in a vicinity of the second flip-flop, and which is included in a domain operating by using the first clock signal. When such a flip-flop does not exist in a system, it is possible to provide, as the fourth flip-flop, a flip-flop dedicated to release or capture the test data.

Note that an at-speed test on capture of the first flip-flop is carried out in an at-speed test in a clock domain to which the first flip-flop belongs. In addition, an at-speed test on release of the second flip-flop is carried out in an at-speed test in a clock domain to which the second flip-flop belongs.

Furthermore, the present invention is understood as a test method in an integrated circuit configured as above.

### BRIEF DESCRIPTION OF THE DRAWINGS

For a more complete understanding of the present invention and the advantages thereof, reference is now made to the following description taken in conjunction with the accompanying drawings.

FIG. 1 is a circuit diagram explaining a concept of a test method according to an embodiment.

FIG. 2 is a view showing a configuration of a flip-flop used for a test in this embodiment.

FIG. 3 is a view showing an image of a positional relationship of the circuits shown in FIG. 1 on an ASIC chip.

FIG. 4 is a view showing an example of a circuit configuration to realize the test according to this embodiment.

FIG. 5 is a view explaining a first test mode in the circuit configuration shown in FIG. 4.

FIG. 6 is a view explaining a second test mode in the circuit configuration shown in FIG. 4.

FIG. 7 is a schematic diagram showing a circuit configuration known in the prior art to carry out an LSSD test.

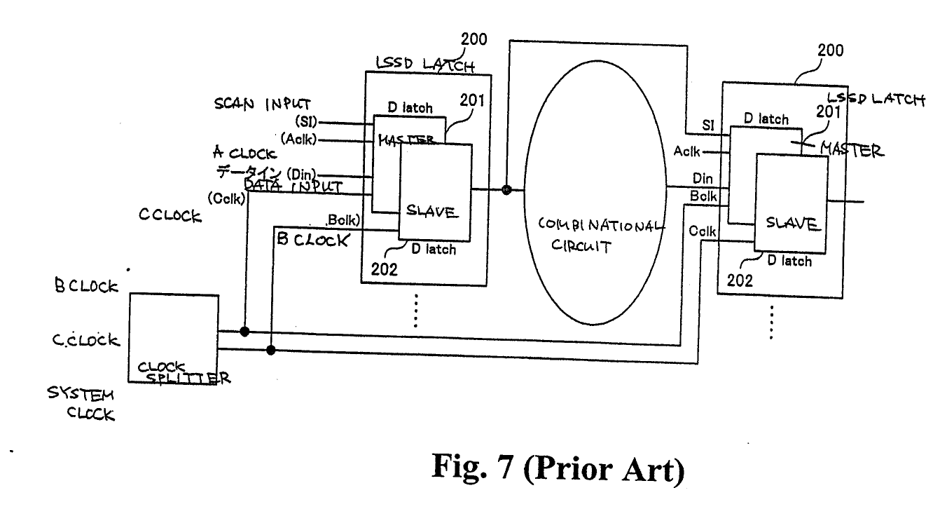

### DETAILED DESCRIPTION OF THE PREFERRED EMBODIMENT

Hereinbelow, with reference to the attached drawings, detailed descriptions will be given of a preferred embodiment mode of the present invention (hereinafter, the embodiment).

Firstly, the outline will be described. In order to carry out an at-speed test of an LSI, based on a pulse outputted from a PLL circuit (a clock generating circuit) in a chip transmitting an operating clock of the integrated circuit (the chip), it is necessary to generate a release clock and a capture clock which have intervals corresponding to the internal frequency of the chip. However, when a test is performed on a cross domain path spanning different clock domains, flip-flops at both ends of this cross domain path operates respectively in accordance with clocks generated in different PLL circuits. Hence, it is extremely difficult to control intervals of the release and capture clocks.

Therefore, the present invention realizes the at-speed test of the cross domain path on the basis of the following points.
(1) It is assumed that a path between domains is “a path within a domain” upon test.
(2) Release and capture clocks of this path are generated in one PLL upon test.
(3) A multiplexer is not inserted to achieve (1) and (2). In other words, the gating of a clock line is not performed.

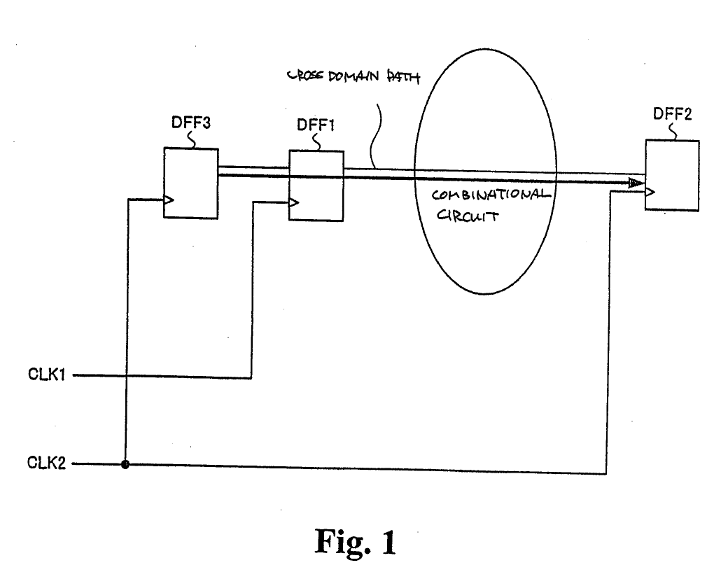

FIG. 1 is a circuit diagram explaining a concept of a test method according to the embodiment.

In FIG. 1, a DFF (flip-flop) 1 operates in accordance with a clock signal CLK 1, and DFFs 3 and 2 operate in accordance with a clock signal CLK 2. The clock CLK 1 and the clock CLK 2 are generated respectively by different phase locked loop (PLL) circuits. Moreover, the DFF 1 data output pin is connected to the DFF 2 data input pin via a combinational circuit.

As can be seen from FIG. 1, the DFF 1, a flip-flop of a CLK 1 domain is interposed between DFFs 3 and 2, both of which are flip-flops of a CLK 2 domain. Accordingly, a path from the DFF 3 to the DFF 2 is focused (the DFF 1 flushes), and release and capture operations are performed by use of the clock signal CLK 2 (a route shown with an arrow in FIG. 1).

In other words, a flip-flop driven by the same clock signal as that of a capture flip-flop is disposed anterior to (on the upstream side) a release flip-flop of a cross domain path. From this flip-flop, test data is released.

Note that the DFF 3 is located in the vicinity of the DFF 1 in FIG. 1 and may be arbitrarily chosen from user latches (flip-flops used in function) driven by using the clock signal CLK 2. Furthermore, when such an appropriate user latch is not found, a DFF 3 dedicated to the test may specially be provided.

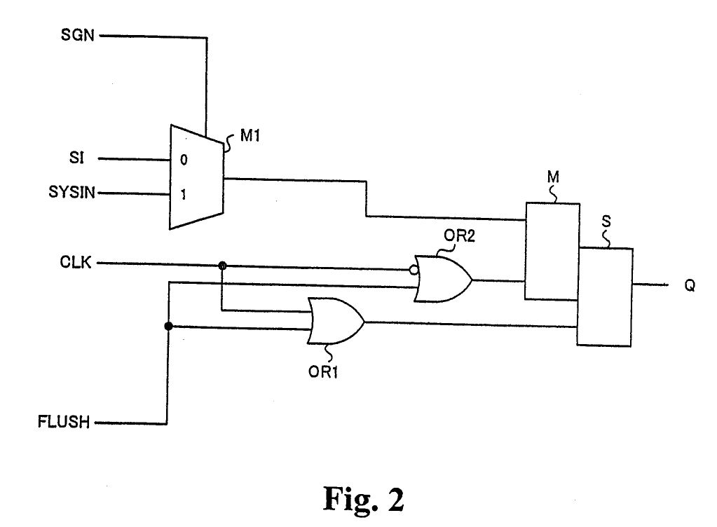

FIG. 2 is a view showing a configuration of a MUXSCAN flip-flop used for the test in the embodiment.

In FIG. 2, when FLUSH is equal to 1, the outputs of both OR circuits OR 1 and OR 2 become “1”. Thereby, two latches M and S become in a flush state. In this state, when SGN is set at 0 in a multiplexer M1, data is flushed from SI to Q in the circuit shown in FIG. 2.

Incidentally, the flip-flop in the drawing is a mere example of a configuration of a MUXSCAN flip-flop having a flush mode. In this embodiment, it is essential that flip-flops located at both ends of a cross domain path have a flush mode (or a through mode) from data input to data output, but the configuration is not limited to the one shown in FIG. 2. It does not matter, for example, to use an LSSD for the test in this embodiment, instead of MUXSCAN flip-flop shown in FIG. 2, since an LSSD latch used for an LSSD test can originally perform flush operation.

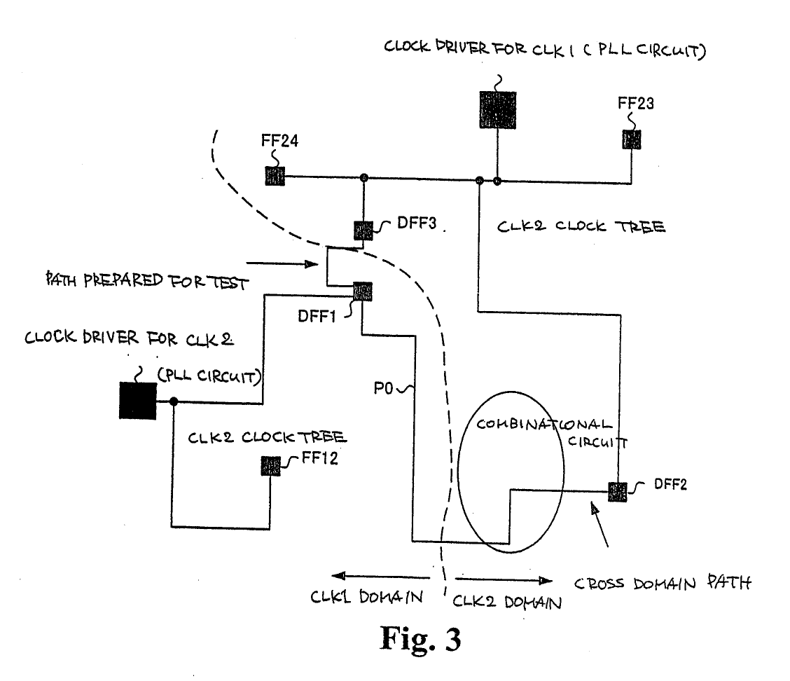

FIG. 3 is a view showing an image of a positional relationship of the circuits, shown in FIG. 1, on an ASIC chip.

Clock trees of the CLK 1 domain and the CLK 2 domain are shown in FIG. 3. A path PO connecting the DFF 1 of the CLK 1 domain to the DFF 2 of the CLK 2 domain is a target path under the test. Here, it can be seen that the DFF 3 of the CLK 2 domain is located in the vicinity of the DFF 1. In such a circuit configuration, an at-speed test on the path PO is carried out by releasing test data from the DFF 3 and by capturing it in the DFF 2.

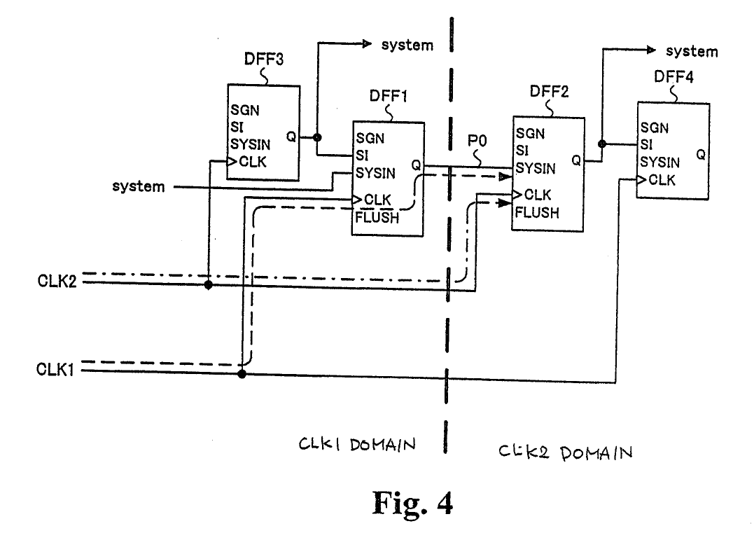

FIG. 4 is a view showing an example of a circuit configuration to realize the test according to this embodiment.

In FIG. 4, the DFFs 1 and 4 are flip-flops driven by using the clock signal CLK 1. Here, the DFFs 2 and 3 are flip-flops driven by using the clock signal CLK 2. Furthermore, the path PO between the DFFs 1 and 2 is a target path. The DFF 3 is a circuit of the CLK 2 domain, which is driven by using the CLK 2, as described above. The DFF 3, however, is illustrated on the CLK 1 domain side for convenience of explanation of the test method of this embodiment.

In the circuit diagrams shown in FIGS. 1 and 3, only the flip-flop DFF 3 for the test is illustrated on the upstream side of the DFF 1 in order to explain the concept of the test. With this configuration, however, an at-speed test on the target path by use of only the CLK 2 can be carried out. In reality, a configuration to carry out a test by use of the CLK 1 is also required. Accordingly, in the configuration shown in FIG. 4, a flip-flop DFF 4, which is similar to DFF 3, for the test is disposed on the downstream side of the DFF 2. This DFF 4 is a circuit of the CLK 1 domain, which is driven by using the CLK 1, as described above. The DFF 4, however, is illustrated on the CLK 2 domain side for convenience of explanation of the test method of this embodiment.

With reference to FIG. 4, in addition, Q output of the DFF 3 is connected to SI of the DFF 1 on the CLK 1 domain side. Moreover, Q output of the DFF 2 is connected to SI of the DFF 4 on the CLK 2 domain side. Then, Q output of the DFF 1 is connected to SYSIN of the DFF 2 with the path PO over the boundary between the CLK 1 domain and the CLK 2 domain.

As described above, the path PO shown in FIG. 4 is a test target in this embodiment. In reality, however, it is necessary to consider the test target including clock lines. The clock lines are configured of a signal propagation path shown with a broken line and a signal propagation path shown with an alternate long and short dashed line in the drawing. In other words, in consideration of signal propagation in the path PO, the following operation is performed. The pulse (clock signal) CLK 1 travels along the path shown with the broken line, and reaches a CLK pin of the DFF 1. In response to this, data is launched from Q of the DFF 1, and reaches SYSIN of the DFF 2 by propagating along the path PO. On the other hand, the pulse (clock signal) CLK 2 travels along the path shown with the alternate long and short dashed line, and reaches CLK of the DFF 2. In response to this, the DFF 2 latches the data which has arrived at SYSIN.

Taking the above into account, carrying out the at-speed test on the path between the DFFs 1 and 2 means none other than testing the following four points.
(A) The DFF 1 captures data at speed.
(B) The DFF 1 releases data at speed.
(C) The DFF 2 captures data at speed.
(D) The DFF 2 releases data at speed.

Since it is impossible to carry out the above-mentioned four tests at the same time, the tests are carried out by being divided into a plurality of modes. Here, the tests (A) and (D) are carried out at speed in the at-speed test within the CLK 1 domain and within the CLK 2 domain, respectively. Therefore, descriptions will hereinafter be given of the tests (B) and (C) in turn.

(First Test Mode)

In a first test mode, the capture of data in the DFF 2 is tested.

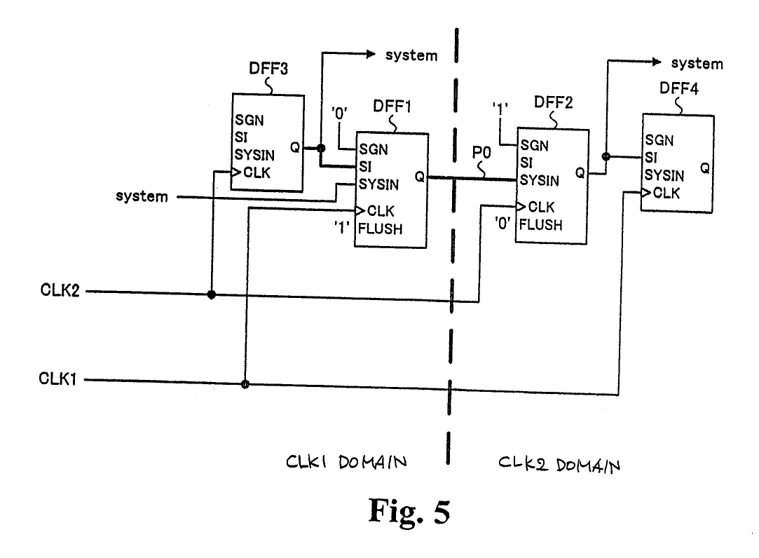

FIG. 5 is a view explaining the first test mode in a circuit diagram shown in FIG. 4.

In FIG. 5, FLUSH is equal to 1 in the DFF 1 and FLUSH is equal to 0 in the DFF 2. Therefore, the DFF 1 flushes inputted data, while the DFF 2 captures the inputted data without flushing.

In this mode, test data is firstly set in the DFF 3. Then, the test data in the DFF 3 is released on receipt of the CLK 2 inputted to the DFF 3. At this time, since the DFF 1 flushes the test data from SI to Q, the test data propagates to the path PO as it is. Then, the DFF 2 captures the test data on receipt of the CLK 2 inputted to the DFF 2.

With the above procedures, the capture of the data by the DFF 2 is tested at speed (the CLK 2). In other words, the above-mentioned test (C) is carried out. Incidentally, a frequency figured out from a speed which a system designer assumes may be used for a frequency upon test in this mode.

(Second Test Mode)

In a second test mode, the release of data in the DFF 1 is tested.

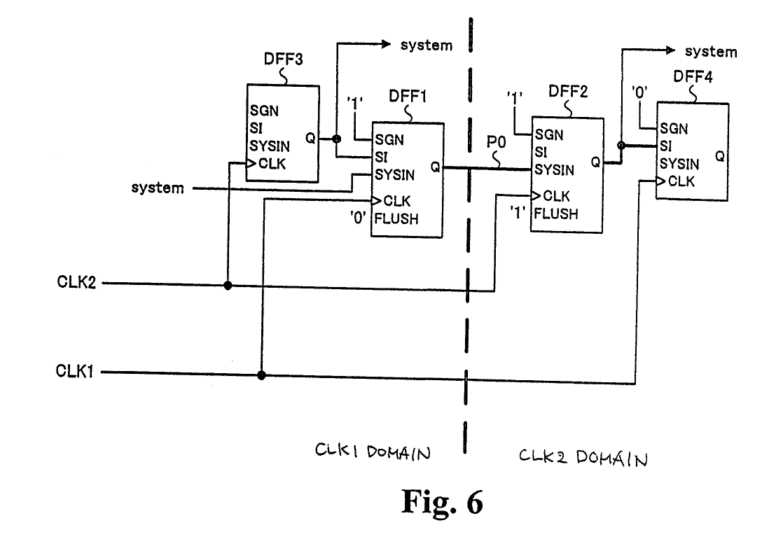

FIG. 6 is a view explaining the second test mode in the circuit configuration shown in FIG. 4.

In FIG. 6, FLUSH is equal to 0 in the DFF 1 and FLUSH is equal to 1 in the DFF 2. Hence, the DFF 1 holds inputted data without flushing, the DFF 2 flushes the inputted data.

In this mode, test data is firstly set in the DFF 1. Then, the test data in the DFF 1 is released on receipt of the CLK 1 inputted to the DFF 1. At this moment, the DFF 2 flushes the test data from SYSIN to Q. Then, the DFF 4 captures the test data on receipt of the CLK 1 inputted to the DFF 4.

With the above procedures, the release of the data by the DFF 1 is tested at speed (the CLK 1). In other words, the above-mentioned test (B) is carried out. Incidentally, a frequency figured out from a speed which a system designer assumes may be used for a frequency upon test in this mode, as in the case of the first test mode.

Moreover, as described above, the flip-flop DFF 4 for the test is used in the second test mode. This DFF 4 is disposed in a vicinity of the DFF 2 as the DFF 3 (the DFF 3 shown in FIG. 1). In addition, a user latch (a flip-flop used in function) driven by using the clock signal CLK 1 can be used as the DFF 4. When such an appropriate user latch does not exist, a DFF 4 dedicated to the test may specially be provided.

With the first and second test modes described above, the at-speed test targeted for a cross domain path is realized.

Note that the descriptions were given of the above-mentioned circuit configuration and test method on the precondition of a skewed load test. However, it is possible to apply the circuit configuration and test method to a broad side band test.

According to the present invention configured as above, it is possible to carry out an at-speed test on a cross domain path, that is, a test on the release and capture operation of data at speed.

Although the preferred embodiment of the present invention has been described in detail, it should be understood that various changes, substitutions and alternations can be made therein without departing from spirit of the inventions as defined by the appended claims.

What is claimed is:

1. An integrated circuit comprising:
a first flip-flop which is capable of flushing, and which operates by using a first clock signal;
a second flip-flop which is capable of flushing, which operates by using a second clock signal, and which is connected to the first flip flop;
a third flip-flop which operates by using the second clock signal, and which is connected to the first flip-flop; and
a fourth flip-flop which operates by using the first clock signal, and which is connected to the second flip-flop,
the integrated circuit wherein a test on a path between the first and the second flip-flops is carried out in:
a test mode in which test data is released from the third flip-flop on receipt of the second clock signal, is flushed by the first flip-flop, and is captured in the second flip-flop; and
a test mode in which test data is released from the first flip-flop on receipt of the first clock signal, is flushed by the second flip-flop, and is captured in the fourth flip-flop.

2. The integrated circuit according to claim 1, wherein the first and the second flip-flops are MUXSCAN flip-flops.

3. The integrated circuit according to claim 1, wherein the first and second flip-flops are LSSD latches used for an LSSD scan test.

4. The integrated circuit according to claim 1, wherein the third flip-flop is a flip-flop which is located in a vicinity of the first flip-flop, which is included in a domain operating by using the second clock signal, and which is used in function.

5. The integrated circuit according to claim 1, wherein the third flip-flop is a flip-flop dedicated for a test, which is provided so as to any of release and capture the test data.

6. The integrated circuit according to claim 1, wherein the fourth flip-flop is a flip-flop which is located in a vicinity of the second flip-flop, which is included in a domain operating by using the first clock signal, and which is used in function.

7. The integrated circuit according to claim 1, wherein the fourth flip-flop is a flip-flop dedicated for a test, which is provided so as to any of release and capture the test data.

8. A test method of an integrated circuit which includes: a first flip-flop which is capable of flushing, and which operates by using a first clock signal; a second flip-flop which is capable of flushing, which operates by using a second clock signal, and which is connected to the first flip flop; a third flip-flop which operates by using the second clock signal, and which is connected to the first flip-flop; and a fourth flip-flop which operates by using the first clock signal, and which is connected to the second flip-flop,
the test method comprising the steps of:
releasing test data from the third flip-flop on receipt of the second clock signal, flushing the test data in the first flip-flop, and capturing the test data in the second flip-flop; and
releasing test data from the first flip-flop on receipt of the first clock signal, flushing the test data in the second flip-flop, and capturing the test data in the fourth flip-flop.
